(19) United States
(12) Patent Application Publication
(10) Pub. No.: US 2026/0089943 A1
(43) Pub. Date: Mar. 26, 2026

(54) Continuous Multi-Slit Cell using less curvature area to minimize non-uniform carrier's injection due to electric field localization

(71) Applicant: SK hynix Inc., Gyeonggi-do (KR)

(72) Inventors: Sungwon LIM, San Jose, CA (US); Tong ZHANG, San Jose, CA (US); Agus TJANDRA, San Jose, CA (US); Sung-Taeg KANG, San Jose, CA (US)

(21) Appl. No.: 18/896,760

(22) Filed: Sep. 25, 2024

(51) Int. Cl. H10B 43/27

(52) U.S. Cl. CPC H10B 43/27

(57) ABSTRACT

A method for making an MSC structure, the method comprising providing a stack of alternating oxide and nitride layers, forming a channel hole having a pillar shape extending through the stack, and forming sequentially a blocking oxide layer, a charge trap nitride layer, a tunnel oxide layer, a channel poly-Si layer and a liner oxide over the sidewall of the channel hole. The method further comprises forming a non-conformal sacrificial layer on the liner oxide, and separating the non-conformal sacrificial layer at a thinner area thereof. The MSC structure is formed on lesser curvature regions of the channel hole for improved cell characteristics.

### FIELD OF THE INVENTION

The present invention generally relates to 3-dimensional (“3-D”) semiconductor technology and, more particularly, to a multi-site cell (MSC) semiconductor technology.

### BACKGROUND

For increased cell integration (or density) in 3D NAND semiconductor devices, advanced memory sell designs storing multiple bits per cell such as 2 (Multi-Level Cells or MLC), 3 (Triple-Level Cells or TLC), 4 (Quad Level Cells or QLC) and even 5 (Penta Level Cells or PLC) compared to Single Logic Cell (SLC) have been developed. Also, various vertical (100, 200, 300, 400 stacks), lateral (4, 9, 14, 19, 24 rows), and structural (4D, PUA, HWB) scaling methods have been proposed. However, these efforts for increasing integration are reaching their limits in terms of physical limitations and high cost. Hence, additional physical scaling methods are needed. One recently proposed method includes formation of multi-site cells, also often referred to as multi-slit cells. Examples of MSC method patents include U.S. Pat. Nos. 11,716,847 B2 and 11,545,190 B2.

### SUMMARY OF THE INVENTION

The present invention relates generally to a continuous MSC (Multi-Site Cell) structure that can secure sufficient channel area with cell cutting (i.e., with no cell structure) while having enough storage nodes. The method employs non-conformal sacrificial layer and carbon gap-fill, and is a very effective method structurally compared to previous multi-slit cell structures which have curvature area.

The present invention includes a method that drastically improves the cell characteristics of the multi-slit cells compared to existing methods. It forms multi-slit cells with less curvature than existing methods do. Also, the formed multi-slit cells have a continuous and sufficient storage node area. The method forms the multi-slit cells by cutting the cell layers using a non-conformal sacrificial layer and a photoresist (PR) or carbon gap-fill after channel poly-Si and liner oxide deposition.

Unlike earlier proposed MSC methods the present inventive method forms a continuous cell with less curvature area by using a cell cutting scheme which employs sacrificial layers in oval, triangular, and quadruple shapes.

Accordingly, a method for making a multi-slit cell (MSC) structure may comprise: providing a stack of alternating films of oxides and nitrides; forming a channel hole having a pillar shape extending through the stack; forming sequentially a blocking oxide layer, a nitride layer, a tunnel oxide layer, a channel poly-Si layer and a liner oxide over the sidewall of the channel hole; forming a non-conformal sacrificial layer on the liner oxide; and separating the non-conformal sacrificial layer at a thinner area thereof.

The method may further comprise filling an opened area of the channel hole with a photoresist or carbon, and removing any remaining sacrificial layer of the non-conformal sacrificial layer by wet cleaning which has enough selectivity for both the liner oxide and the photoresist or the carbon. The photoresist or the carbon cover the liner oxide that is exposed following the separating of the non-conformal sacrificial layer.

The liner oxide may be a thin liner oxide having, for example, a thickness of 3 to 5nm.

The method provides a plurality of active cell areas at both sides of each level of the channel hole. The active channel areas are covered by the carbon which remains during the dry or wet etching operations for protecting the active cell areas.

The method may further comprise removing the carbon and gap-filling an opened space created by the removing of the carbon with an oxide.

The channel hole may have an oval, triangular, or quadruple type cross-sectional shape.

The method may further comprise separating the liner oxide, the channel poly-Si, the tunnel oxide layer, and the charge trap nitride layer of the opened area through a dry or wet etching to form continuous multi-slit cells. These operations may be performed sequentially. In order to obtain proper cell separation a wet cleaning or a dry etching may have sufficient selectivity for each oxide, poly-Si, and nitride. For example, when separating the thin liner oxide, it should have the characteristics of having little or no loss for both the poly-Si, and photoresist or carbon.

The multi-slit cells are disposed at both sides of the channel hole and are covered by the photoresist or the carbon which remains during the dry or wet etching.

The method may further comprise removing the photoresist or the carbon and gap-filling an opened space created by the removing of the photoresist or the carbon with an oxide.

According to an embodiment, a method for making a semiconductor device with a multi-slit cell structure is provided. The method comprises: forming a channel hole extending through a stack of alternating oxide and nitride layers, the channel hole having a cross-sectional oval shape having curved areas along a long axis of symmetry of the channel hole and less curvature areas along a short axis of symmetry of the channel hole; forming sequentially a blocking oxide layer, a charge trap nitride layer, a tunnel oxide layer, a channel poly-Si layer and a liner oxide over a sidewall of the channel hole; forming a non-conformal sacrificial layer on the liner oxide, the non-conformal sacrificial layer being thicker on the curved areas along the long axis of channel hole and thinner on the less curvature areas along the short axis of the channel hole; and separating the non-conformal sacrificial layer by removing the thinner thickness areas of the non-conformal sacrificial layer to expose the liner oxide.

The method may further comprise filling an opened area of the channel hole with carbon, and removing any remaining sacrificial layer of the non-conformal sacrificial layer by wet cleaning which has enough selectivity for both the liner oxide and the carbon.

The method may further comprise separating the liner oxide, the channel poly-Si layer, the tunnel oxide layer, and the charge trap nitride layer of the opened area through dry or wet etching to form a plurality of active cell areas disposed at both sides of the channel hole and are covered by the carbon which remains during the dry or wet etching.

The method may further comprise removing the carbon and gap-filling an opened space created by the removing of the carbon with an oxide.

The method may further comprise exhuming the nitride layers from the stack and forming word lines in spaces formed by the exhuming of the nitride layers.

In yet another embodiment, a method for making a semiconductor device may comprise providing a stack of alternating oxide and nitride layers, and forming a channel hole having a pillar shape extending through the stack. The channel hole may have curved areas along a long axis of symmetry of the channel hole and less curvature areas along a short axis of symmetry of the channel hole The method further includes forming cell areas, each cell area being disposed on a corresponding one of the less curvature areas along the short axis of the channel hole, gap-filling an open space of the channel hole which is not covered by the cell areas with an oxide, exhuming the nitride layers from the stack; and forming word lines in spaces of the stack that are formed by the exhuming of the nitride layers from the stack.

The forming of the cell areas may include forming sequentially a blocking oxide layer, a charge trap nitride layer, a tunnel oxide layer, a channel poly-Si layer and a liner oxide over a sidewall of the channel hole, and forming a non-conformal sacrificial layer on the liner oxide, the non-conformal sacrificial layer being thicker on the curved areas aligned along the long axis of the channel hole and thinner on the less curvature areas aligned along the short axis of the channel hole. The forming of the cell areas further includes separating the non-conformal sacrificial layer by removing the thinner thickness areas of the non-conformal sacrificial layer to expose the liner oxide, and filling an opened area of the channel hole following the separating of the non-conformal sacrificial layer with carbon.

Any remaining sacrificial layer of the non-conformal sacrificial layer may then be removed by wet cleaning which has enough selectivity for both the liner oxide and the carbon.

The method further includes separating the liner oxide, the channel poly-Si layer, the tunnel oxide layer, and the charge trap nitride layer of the opened area to form the cell areas.

The channel hole may have an oval cross-sectional shape.

These and other features and advantages of the present invention will become apparent to those skilled in the art of the invention from the following detailed description in conjunction with the following drawings.

### BRIEF DESCRIPTION OF THE FIGURES

FIGS. 1A to 15C illustrate a method of making MSC structure according to an embodiment of the present invention. FIGS. 1A to 15A are plan views of an oval shape channel structure, FIGS. 1B to 15B are cross-sectional views taken along line A-A′ of the corresponding FIGS. 1A to 15A, and FIGS. 1C to 15C are cross-sectional views taken along line B-B′ of the corresponding FIGS. 1A to 15A.

### DETAILED DESCRIPTION OF THE INVENTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly on the second layer or the substrate.

It should be understood that the drawings are simplified schematic illustrations of the described devices and may not include well known details for avoiding obscuring the features of the invention.

It should also be noted that features present in one embodiment may be used with one or more features of another embodiment without departing from the scope of the invention.

It is further noted, that in the various drawings, like reference numbers designate like elements.

As used herein, singular forms are intended to include the plural forms as well, unless the context clearly indicates otherwise.

According to an aspect of the present invention, a method is provided which can significantly improve the cell characteristics of multi-slit cells compared to existing technologies by discretizing a sufficient storage node area recessed through a sacrificial blocking layer and securing a sufficient string current while cutting the channel poly-Si by a non-conformal sacrificial layer after a channel poly-Si deposition process for each cell to reduce string current degradation due to the channel cutting operation.

According to an embodiment, a layered structure of alternating thin films of oxides (“O”) and nitrides (“N”) is provided, referred to hereinafter as an ONO stack. Then, a channel hole is formed having a pillar shape extending through the ONO stack along a first axis perpendicular to the ONO stack. The method of forming the multi-slit cell structure includes a pillar etching operation to form the channel hole passing through the ONO stack. The channel hole may have an oval cross-sectional shape extending through the stack. Then, a first oxide layer, also referred to as a blocking oxide layer, is deposited on the sidewall of the channel hole for electrical insulation from the word line (“WL”) layers which are formed later according to the described method. Then, a nitride layer is deposited on the first oxide layer to cover the first oxide layer. The nitride layer may be used to form the storage node for the MSC structure. Afterward, a second oxide layer, also referred to as the tunnel oxide layer, is formed on the nitride layer to cover the nitride layer. The second oxide layer may be formed, for example, by the same ONO deposition tool at one time, and then a channel poly-Si layer is applied on the second oxide layer. The deposition of the channel poly-Si layer may be performed using any suitable existing method such as, for example, low pressure chemical vapor deposition (LPCVD). The channel poly-Si layer is covered by a thin third oxide layer, also referred to as a liner oxide to block poly-Si damage during the cell-cutting process. Furthermore, to proceed with the cell-cutting process for forming a continuous MSC (Multi Slit Cell), a non-conformal sacrificial layer is formed. The non-conformal sacrificial layer may include poly-Si, nitride (Si3N4), metal, metal nitride, and metal silicide and may be formed by chemical vapor deposition (CVD), low pressure chemical vapor deposition (LPCVD), or atomic layer deposition (ALD). Afterward, the non-conformal sacrificial layer is separated at a thinner area instead of a thicker area thereof. For example, the non-conformal sacrificial layer may be separated by a dry or wet separation process. Then, the opened area is filled with a PR (photoresist) or carbon to cover the active cell area. A spin-on-coating (SOC) method may be used for filling the open area with the PR or the carbon. Any suitable carbon may be used. The choice of carbon material may depend on the particular type of semiconductor device, and may include, for example, carbon nanotubes, graphene, amorphous carbon, diamond-like carbon, carbon nanodots, and the like. In an embodiment, amorphous carbon may be used via LT-SOC (Low Temperature Spin on Carbon) or HT-SOC (High Temperature Spin on Carbon).

After the forming of the PR or carbon, any remaining sacrificial layer is removed. For removing the remaining sacrificial layer any suitable operation may be used. For example, any remaining sacrificial layer may be removed by wet cleaning which has enough selectivity for both the liner oxide and the gap-filled carbon. The remaining sacrificial layer exposed between the liner oxide and carbon is removed with wet etching having sufficient selectivity. Various types of films may be applied as a sacrificial layer, and various wet etchants may be applied for each type of sacrificial layer provided they have sufficient selectivity for both the liner oxide and the gap-filled carbon.

The method further includes separating the thin liner oxide, the channel poly-Si, the tunnel oxide layer, and the charge trap nitride layer of the opened areas through a dry or wet etching process to form continuous multi-slit cells. At this time, the cell layers at both sides (the less curved sides) of the oval shape channel hole are covered by the carbon or PR which forms a barrier and remains substantially intact during the dry or wet etching operations. The next operation includes removing the gap-filled PR or carbon through a dry or wet cleaning process and gap-fill with oxide. The present inventive method is advantageous because it secures enough channel area for the multi-slit cells and also that each multi-slit cell has less curvature.

This invention relates to a method of forming multi-slit cells by cutting the storage layer by cell cutting using a sacrificial blocking layer and gap-filled carbon in oval, triangular, and quadruple shapes. The conventional cell structure physically forms one cell per layer on one pillar, but when the storage layer is separated according to this invention, each separated cell area can function as an independent cell. Therefore, this is an invention that can dramatically overcome the limitations of vertical scaling in current 3D NAND devices. This invention is a method of dividing the storage layer by using a sacrificial blocking layer (such as non-conformal film deposition) and gap-filled carbon.

Also, the inventive method can secure sufficient storage nodes and less curved multi slit cells for lower non-uniform carrier injection compared to the previous channel-cutting scheme which have smaller as well as curved channel areas.

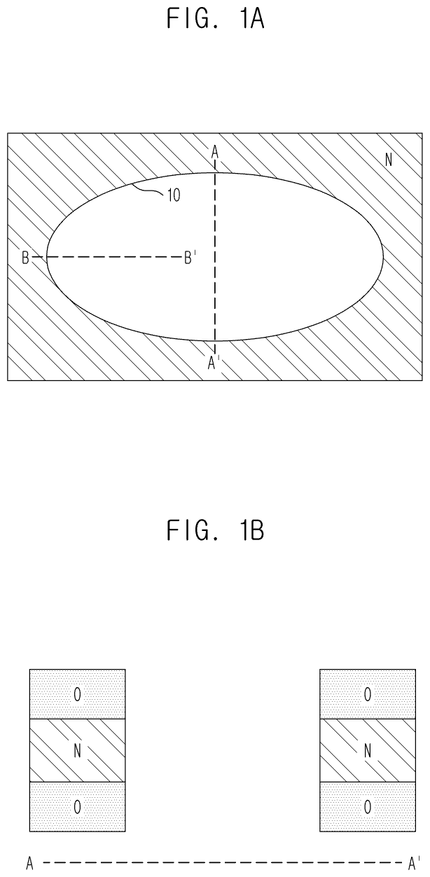

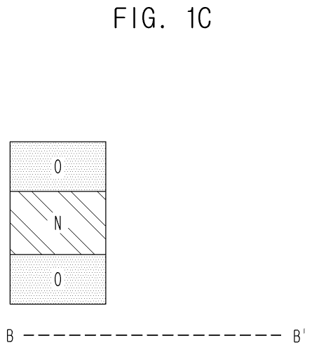

Referring now to FIGS. 1A, 1B, and 1C, the method for making the MSC comprises providing a stack of alternating thin films of oxides (“O”) and nitrides (“N”) and forming a channel hole CH 10 in the form of a pillar extending through the ONO stack along a first axis perpendicular to the ONO stack. The stack may be a NAND stack for a 3D-NAND flash memory.

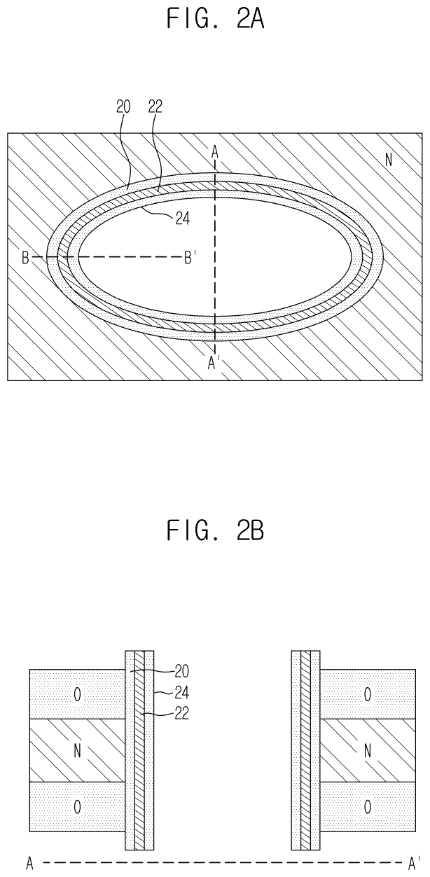

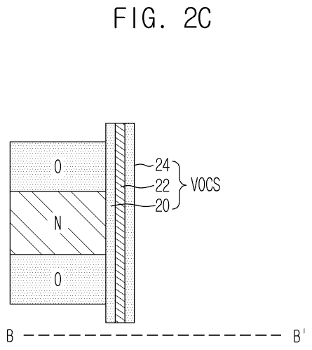

Referring to FIGS. 2A, 2B, and 2C, the method further comprises covering the sidewall of the channel hole 10 with a first oxide layer 20, then a nitride layer 22 formed on the first oxide layer, and then a second oxide layer 24 formed on the nitride layer 22. The nitride layer 22 may have a larger thickness than the first and second oxide layers 20, 24. The first and second oxide layers 20 and 24 may have the same thickness, however, the invention is not limited in this way. The formation of the first oxide, the nitride, and the second oxide layers 20, 22, and 24 may also be referred to as cell formation-1. The stack of the first oxide, the nitride, and the second oxide layers 20, 22, and 24 may also be referred to as a vertical ONO cover stack or VOCS.

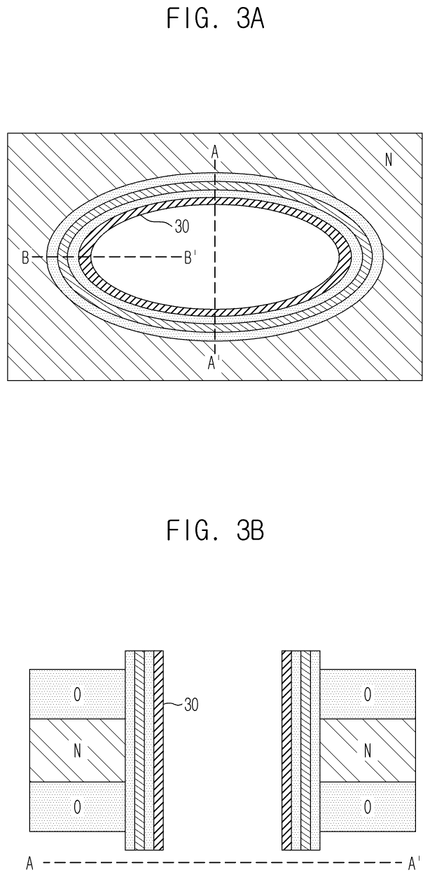

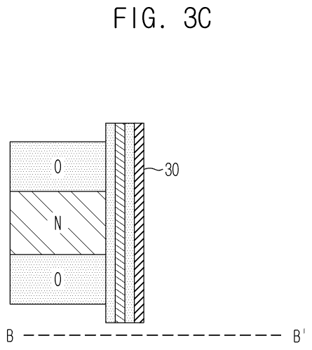

The method further comprises forming a poly-Si layer 30 conformally on the second oxide layer 24 of the vertical ONO cover stack VOCS as shown in FIGS. 3A-3C.

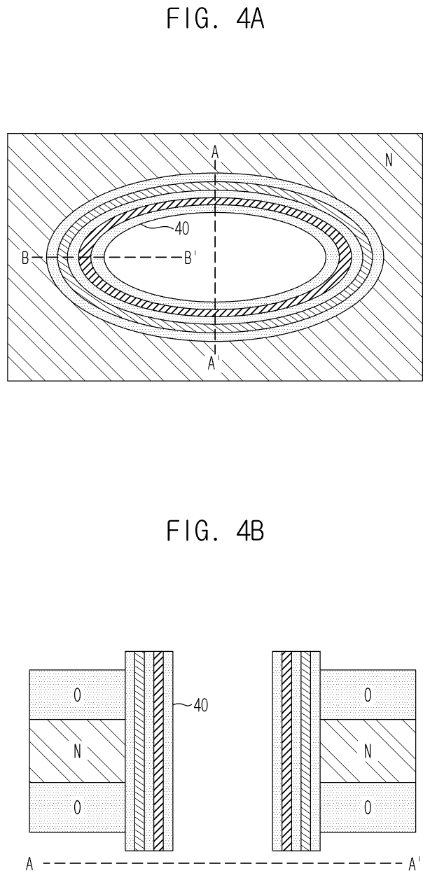

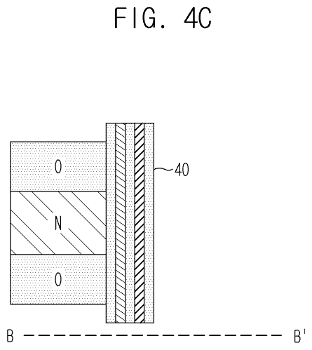

Referring now to FIGS. 4A-4C, a thin liner oxide 40 is formed using an ALD (Atomic Layer Deposition) method.

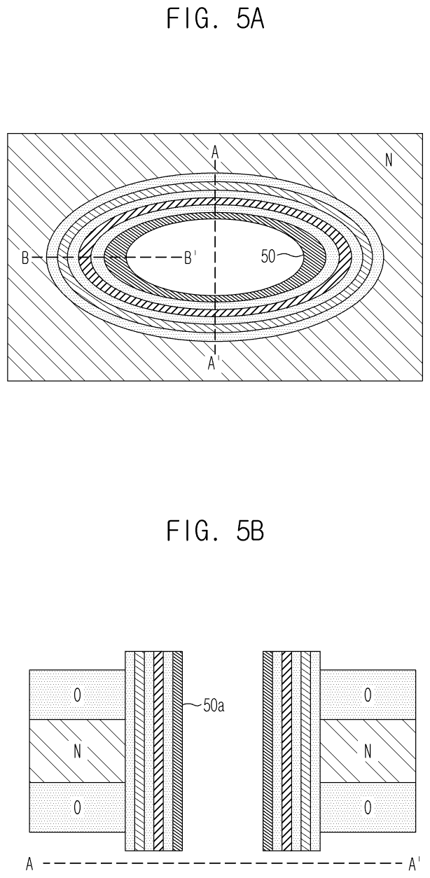

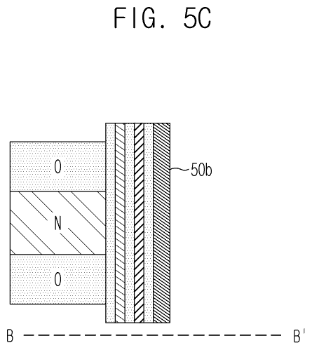

The method further comprises forming a non-conformal sacrificial layer 50 on the gap-fill liner oxide 40 as shown in FIGS. 5A-5C. The forming of the sacrificial layer 50 may include depositing a sacrificial material such as poly-Si, nitride (Si₃N₄) or a metal film formed via CVD, or LPCVD to have a shape with two thicker-thickness areas 50b and two thinner-thickness remaining areas 50a. Each of the two thinner-thickness remaining areas 50a is disposed between the two thicker thickness areas 50b. In other words, the thinner-thickness remaining areas 50a may be alternating with the thicker thickness areas 50b. More specifically, the two thicker-thickness areas 50b may be aligned along the long axis of symmetry of the oval shape channel hole, and the two thinner-thickness areas 50a may be aligned along the short axis of symmetry of the oval shape channel hole. Stated differently, the non-conformal sacrificial layer is formed to be thicker on the curved areas aligned along the long axis of the channel hole and thinner on the less curvature areas aligned along the short axis of the channel hole.

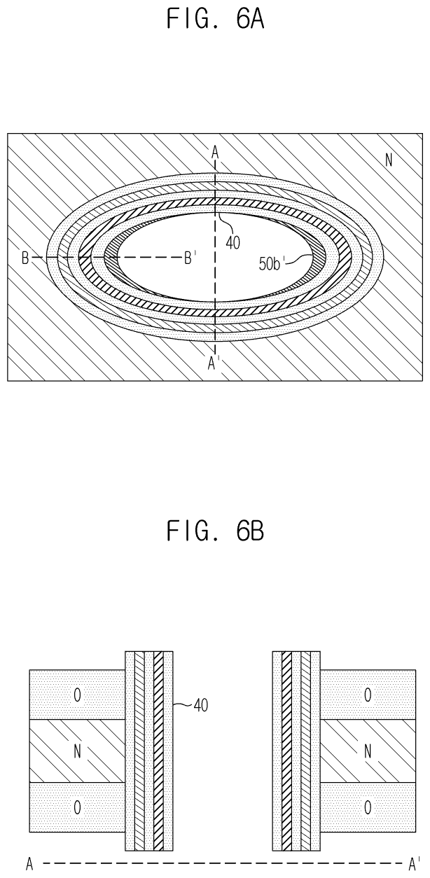

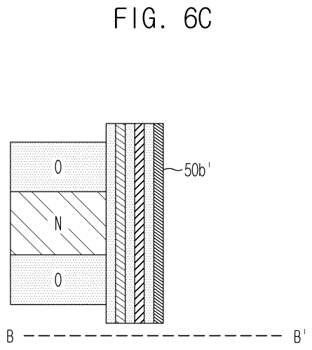

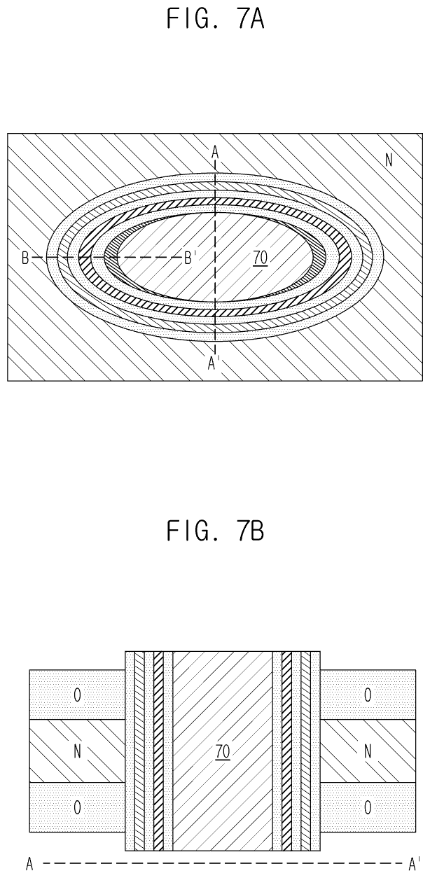

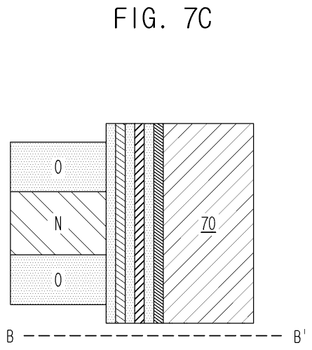

The method further comprises separating the sacrificial layer 50 as shown in FIGS. 6A, 6B, and 6C. For example, the sacrificial layer 50 may be separated through a wet or dry etching operation. In an embodiment, the separating of the sacrificial layer 50 may include performing an isotropic etching operation to separate the two thicker-thickness areas 50b of the sacrificial layer 50 by removing the two thinner-thickness areas 50a of the sacrificial layer 50. Following the isotropic etching operation, thinner sacrificial blocking layer areas 50b′ with a reduced thickness remain only at the previously two thicker thickness areas. The previously thinner sacrificial blocking layer areas 50a are removed and in these areas the gap fill liner oxide 40 is exposed. Once the sacrificial layer 50 is separated and the gap fill liner oxide 40 is exposed, the channel hole is gap filled with PR or carbon 70 as illustrated in FIGS. 7A-7C.

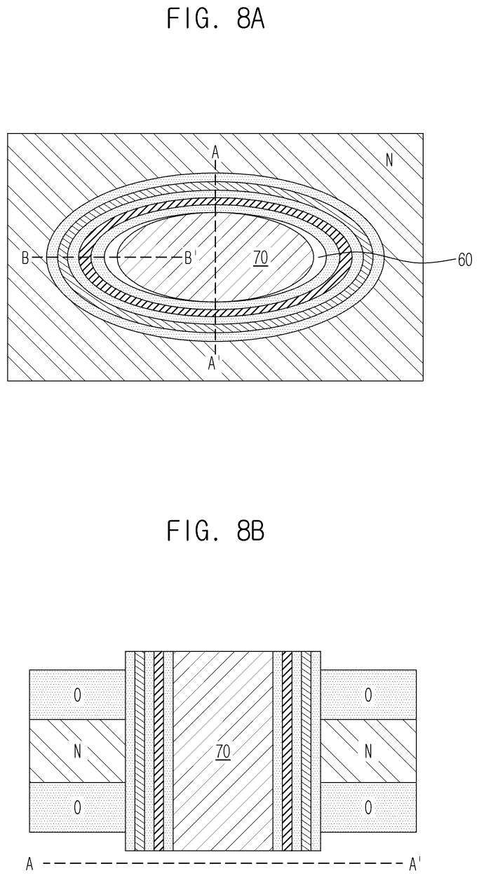

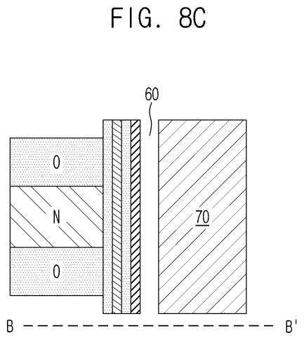

The method further comprises exhuming the remaining sacrificial layer areas 50b′ as shown in FIGS. 8A and 8C. The exhuming of the remaining sacrificial layer areas 50b′ may include wet cleaning which has enough selectivity for both the liner oxide 40 and the gap-filled carbon 70. The voids formed by the removal of the remaining sacrificial layers are denoted with numeral 60.

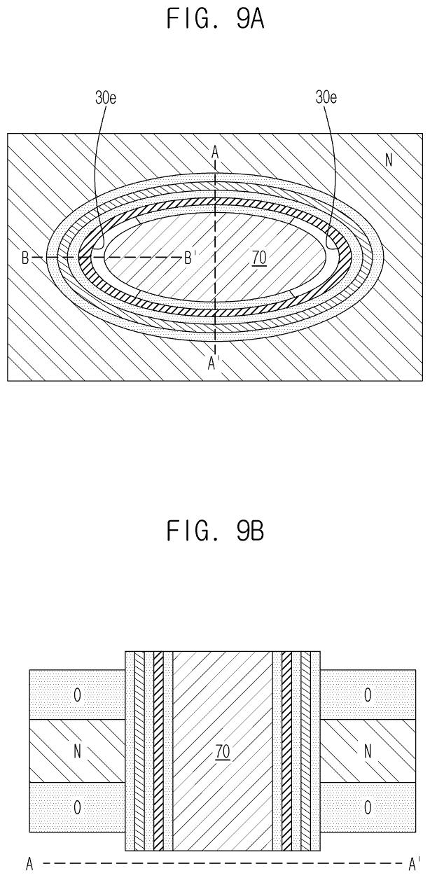

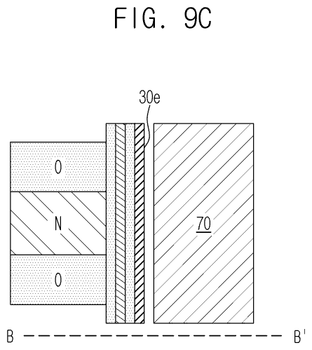

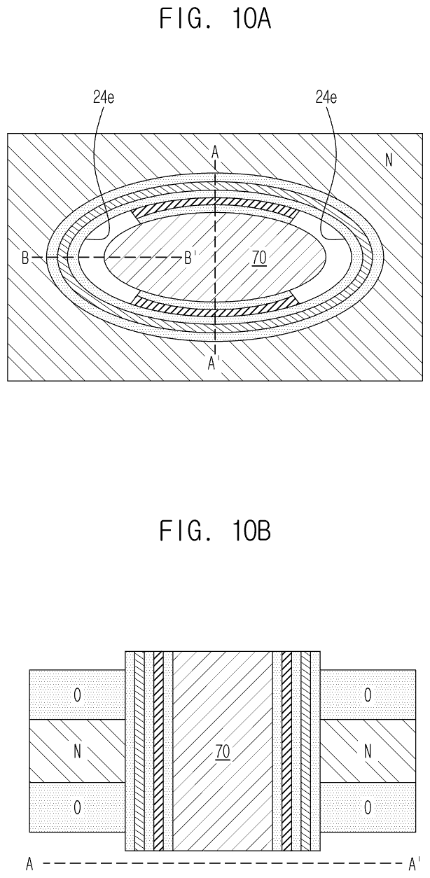

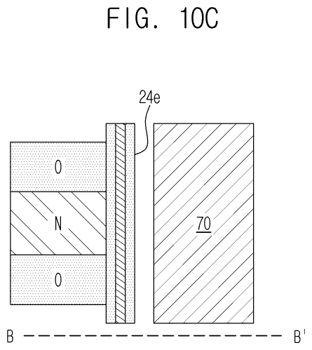

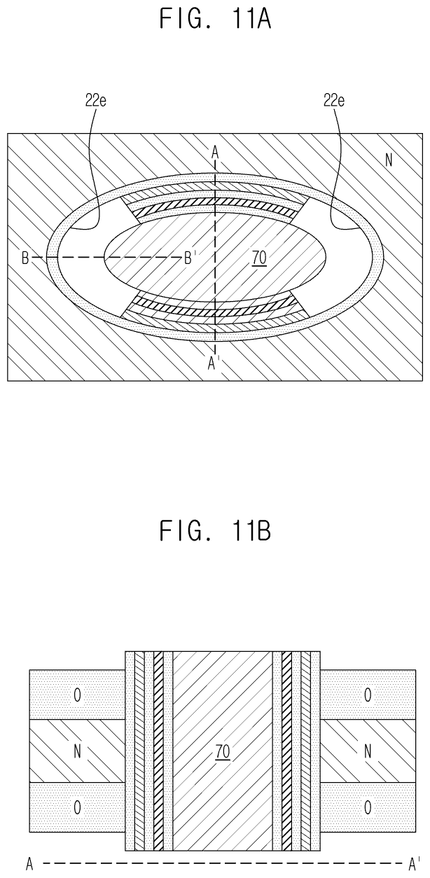

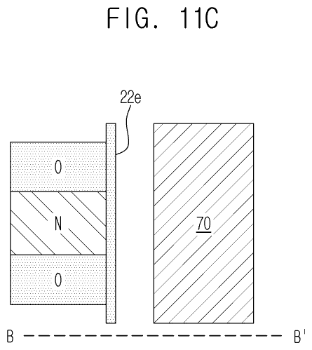

The method further comprises an oxide cut operation as illustrated in FIGS. 9A-9C which includes removing the gap-fill liner oxide 40 to expose the poly-Si layer 30. The removing of the gap-fill liner oxide 40 may be performed, for example, with selective wet etching. More specifically, the areas of the poly-Si layer which are exposed are denoted with numeral 30e and are aligned along the long axis of symmetry of the oval shape channel hole. Then, as illustrated in FIGS. 10A to 10C, the exposed poly-Si layer areas 30e are removed by wet cleaning to expose parts of the second oxide layer 24 of the vertical ONO cover stack VOCS. The exposed areas of the second oxide layer 24 are denoted with numeral 24e and are aligned along the long axis of symmetry of the oval shape channel hole. Subsequently, as shown in FIGS. 11A-11C the exposed areas of the second oxide layer 24e are removed by wet cleaning to expose portions of the nitride layer 22 of the vertical ONO cover stack VOCS. More specifically, the areas of the nitride layer that are exposed are along the short axis of symmetry of the oval shape channel hole and are denoted with numeral 22e.

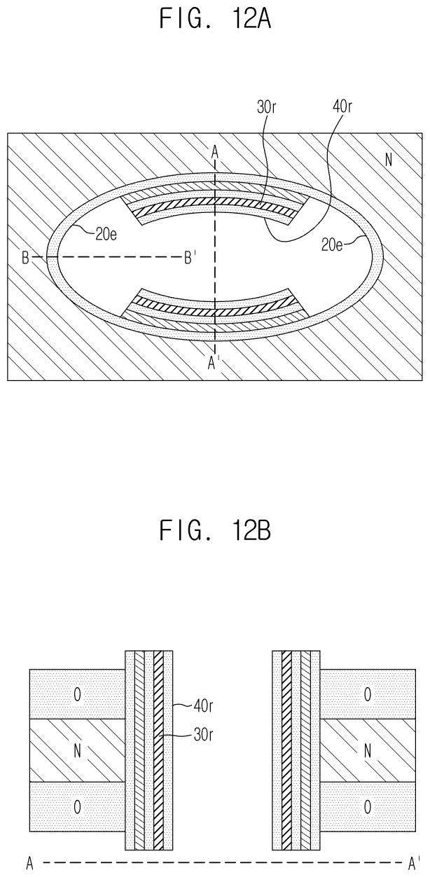

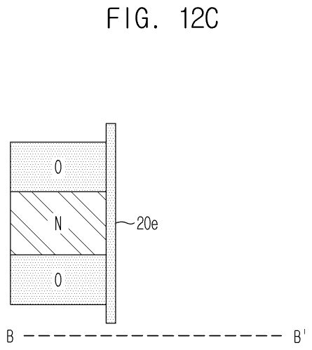

The method further includes a charge trap nitride (CTN) cut and carbon exhume operation as shown in FIGS. 12A-12C which removes the exposed nitride layer areas 22e and exposes portions of the first oxide layer of the vertical ONO cover stack which are denote with numeral 20e. This operation also removes the PR or carbon 70 to expose the portions of the thin liner oxide 40 covering the portions of the poly-Si layer which remain on opposite sides of the channel hole along the short axis of symmetry of the oval shape channel hole. The portions of the poly-Si layer which remain on opposite sides of the channel hole are denoted with numeral 30r and the thin oxide liner over these portions are denoted with numeral 40r.

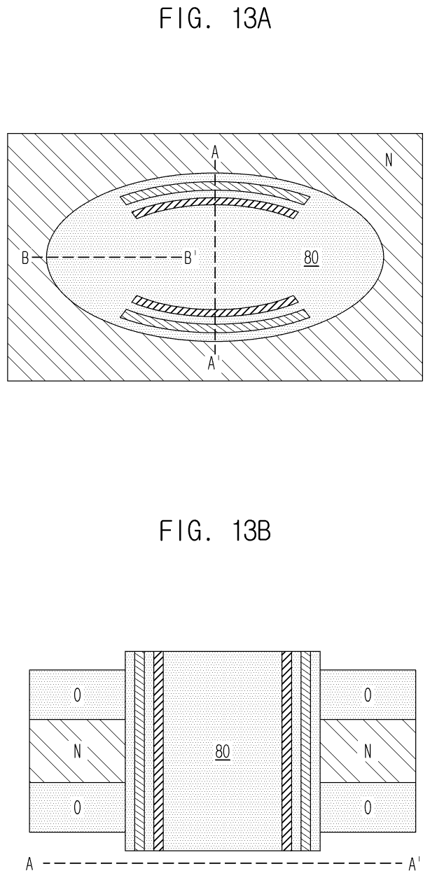

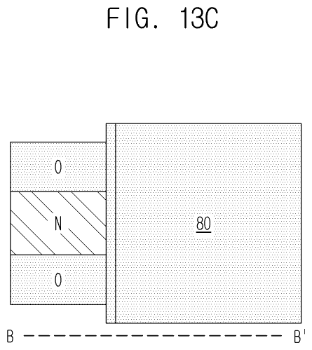

As shown in FIGS. 13A-13C, the open space formed in the operation illustrated in FIGS. 12A-12C is gap-filled with oxide 80.

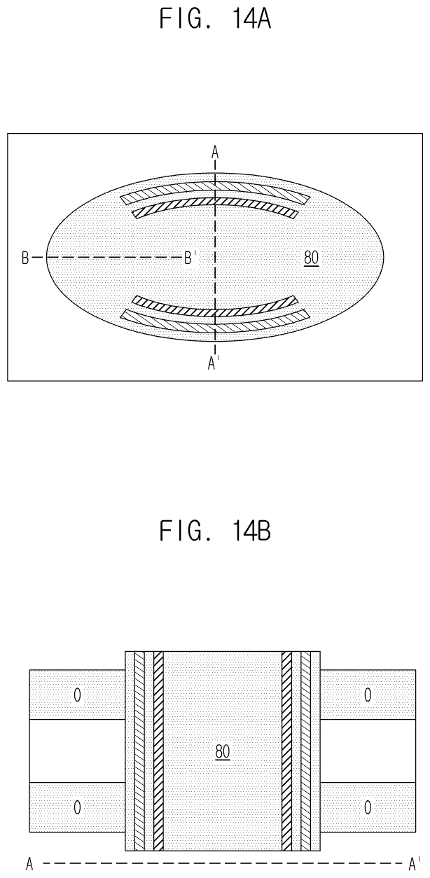

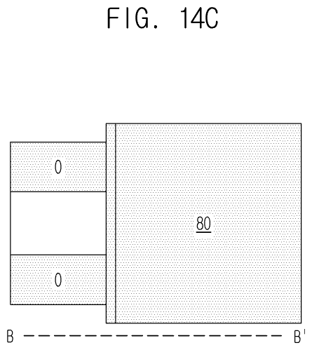

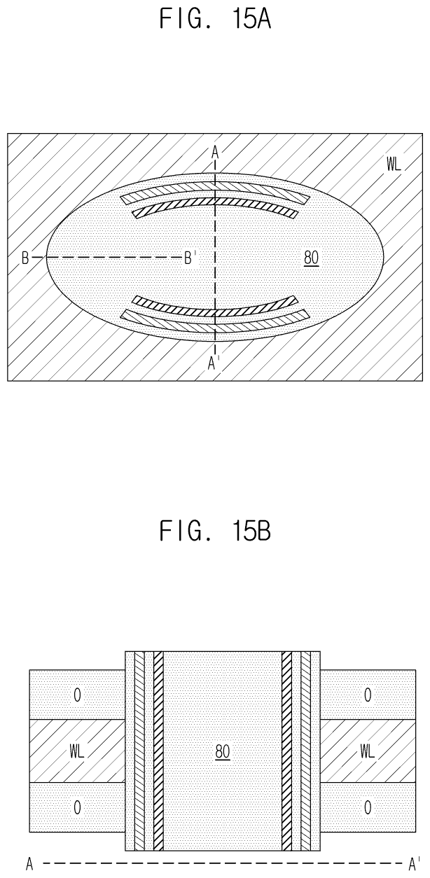

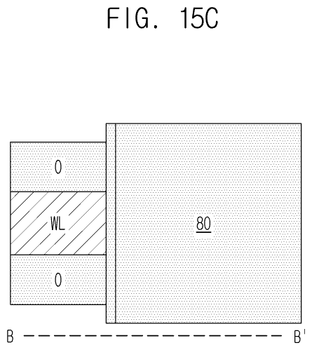

In the next operation shown in FIGS. 14A-14C, the tier nitride layers are removed. The method may further include a metallization operation for forming word lines WL in the former nitride layers of the ONO stack as illustrated in FIGS. 15A-15C. Metallization may include depositing one of aluminum oxide (AlO3), titanium nitride (TiN) and tungsten (“W”) to form word lines as shown in FIGS. 15A to 15C.

Although the invention has been described in reference to a dual slit cell embodiment, the present invention generally relates to a method of forming multi-slit cells. The conventional cell structure physically forms one cell per layer on one pillar, but according to the present invention method each separated section of a cell can function as an independent cell. Therefore, the present invention can dramatically overcome the limitations of vertical scaling in current 3D NAND semiconductor devices.

What is claimed is:

1. A method for making a multi-slit cell structure, the method comprising:
providing a stack of alternating films of oxides and nitrides;
forming a channel hole having a pillar shape extending through the stack;
forming sequentially a blocking oxide layer, a nitride layer, a tunnel oxide layer, a channel poly-Si layer and a liner oxide over a sidewall of the channel hole;
forming a non-conformal sacrificial layer on the liner oxide; and
separating the non-conformal sacrificial layer by a dry or wet separation process at a thinner area thereof.

2. The method of claim 1, further comprising filling an opened area of the channel hole with a photoresist or carbon, and removing any remaining sacrificial layer of the non-conformal sacrificial layer by wet cleaning which has enough selectivity for both the liner oxide and the photoresist or the carbon.

3. The method of claim 1, wherein the channel hole may have an oval, triangular, or quadruple type cross-sectional shape.

4. The method of claim 3, further comprising separating the liner oxide, the channel poly-Si layer, the tunnel oxide layer, and the nitride layer of the opened area through a dry or wet etching process to form continuous multi-slit cells.

5. The method of claim 4, wherein the multi-slit cells are disposed at both sides of the channel hole and are covered by the photoresist or the carbon which remains during the dry or wet etching.

6. The method of claim 5, further comprising removing the photoresist or the carbon and gap-filling an opened space created by the removing of the photoresist or the carbon with oxide.

7. A method for making a semiconductor device with a multi-slit cell structure, the method comprising:
forming a channel hole extending through a stack of alternating oxide and nitride layers, the channel hole having a cross-sectional oval shape having curved areas along a long axis of symmetry of the channel hole and less curvature areas along a short axis of symmetry of the channel hole;
forming sequentially a blocking oxide layer, a charge trap nitride layer, a tunnel oxide layer, a channel poly-Si layer and a liner oxide over a sidewall of the channel hole;
forming a non-conformal sacrificial layer on the liner oxide, the non-conformal sacrificial layer being thicker on the curved areas along the long axis of the channel hole and thinner on the less curvature areas along the short axis of the channel hole; and
separating the non-conformal sacrificial layer by removing the thinner non-conformal sacrificial layer to expose the liner oxide.

8. The method of claim 7, further comprising filling an opened area of the channel hole with carbon, and removing any remaining sacrificial layer of the non-conformal sacrificial layer by wet cleaning which has enough selectivity for both the liner oxide and the carbon.

9. The method of claim 8, further comprising separating the liner oxide, the channel poly-Si layer, the tunnel oxide layer, and the charge trap nitride layer of the opened area through dry or wet etching to form a plurality of active cell areas disposed at both sides of the channel hole and are covered by the carbon which remains during the dry or wet etching.

10. The method of claim 9, further comprising removing the carbon and gap-filling an opened space created by the removing of the carbon with an oxide.

11. The method of claim 10, further comprising:
exhuming the nitride layers; and
forming word lines in spaces formed by the exhuming of the nitride layers.

12. A method for making a semiconductor device, the method comprising:
providing a stack of alternating oxide and nitride layers;
forming a channel hole having a pillar shape extending through the stack, the channel hole having curved areas along a long axis of symmetry of the channel hole and less curvature areas along a short axis of symmetry of the channel hole;
forming cell areas, each cell area being disposed on a corresponding one of the less curvature areas along the short axis of the channel hole;
gap-filling an open space of the channel hole which is not covered by the cell areas with an oxide;
exhuming the nitride layers from the stack; and
forming word lines in spaces of the stack that are formed by the exhuming of the nitride layers from the stack.

13. The method of claim 12, wherein the forming of the cell areas includes:
forming sequentially a blocking oxide layer, a charge trap nitride layer, a tunnel oxide layer, a channel poly-Si layer and a liner oxide over a sidewall of the channel hole;
forming a non-conformal sacrificial layer on the liner oxide, the non-conformal sacrificial layer being thicker on the curved areas aligned along the long axis of the channel hole and thinner on the less curvature areas aligned along the short axis of the channel hole;
separating the non-conformal sacrificial layer by removing the thinner thickness areas of the non-conformal sacrificial layer to expose the liner oxide;
filling an opened area of the channel hole following the separating of the non-conformal sacrificial layer with carbon;
removing any remaining sacrificial layer of the non-conformal sacrificial layer by wet cleaning which has enough selectivity for both the liner oxide and the carbon; and
separating the liner oxide, the channel poly-Si layer, the tunnel oxide layer, and the charge trap nitride layer of the opened area to form the cell areas.

14. The method of claim 13, wherein the channel hole has an oval cross-sectional shape.
